(19) United States
(12) Patent Application Publication
(10) Pub. No.: US 2025/0091075 A1
(43) Pub. Date: Mar. 20, 2025

(54) SUBSTRATE PROCESSING APPARATUS AND SUBSTRATE PROCESSING METHOD

(71) Applicant: SEMES CO., LTD., Cheonan-si (KR)

(72) Inventor: Young Jun SON, Cheonan-si (KR)

(21) Appl. No.: 18/778,898

(22) Filed: Jul. 19, 2024

(30) Foreign Application Priority Data
Sep. 14, 2023 (KR) 10-2023-0122214

(51) Int. Cl. B05B 12/08; B05B 12/14

(52) U.S. Cl. CPC B05B 12/084; B05B 12/1427

(57) ABSTRACT

Provided are a substrate processing apparatus and a substrate processing method. The substrate processing apparatus includes a substrate support portion supporting a substrate, a first discharge unit including a first nozzle discharging a first processing liquid to the substrate, a first measurement unit connected to the first nozzle and measuring a first amount of charges of the first processing liquid discharged from the first nozzle, a bowl disposed around the substrate support portion, a second measurement unit measuring a second amount of charges of the first processing liquid scattered from the substrate to the surface of the bowl, and a second discharge unit including a second nozzle discharging a second processing liquid charged based on a difference between the first amount of charges and the second amount of charges to the substrate.

### CROSS-REFERENCE TO RELATED APPLICATION(S)

This application claims benefit of priority to Korean Patent Application No. 10-2023-0122214 filed on Sep. 14, 2023 in the Korean Intellectual Property Office, the disclosure of which is incorporated herein by reference in its entirety.

### BACKGROUND

### 1. Field

The present disclosure relates to a substrate processing apparatus and a substrate processing method.

### 2. Description of Related Art

To manufacture semiconductor devices, a liquid processing process has been widely used to process a substrate by supplying one or more processing liquids to the substrate. Examples of liquid processing processes include a coating process of supplying a photoresist to a substrate to form a liquid film on the substrate and a cleaning process of supplying a cleaning solution to the substrate to remove contaminants, such as particles, organic contaminants, or metal contaminants remaining on the surface of the substrate.

Depending on the properties of the processing liquid used in the liquid processing process, a charging phenomenon may occur in the substrate. When the substrate is charged, fine particles may be easily adsorbed to the substrate, which may reduce the reliability of the process. Therefore, it is important to prevent charging of the substrate or properly remove charged static electricity.

In particular, a technology was needed that could detect the amount of charges on the substrate and cancel it out appropriately, while minimizing the impact on the substrate processing process.

### RELATED ART DOCUMENT

### Patent Document

(Patent Document 1) KR 10-2017-0037841

### SUMMARY

An aspect of the present disclosure is to provide a substrate processing apparatus and a substrate processing method capable of compensating for the amount of charges in a substrate, while performing a chemical processing process.

Another aspect of the present disclosure is to provide a substrate processing apparatus and a substrate processing method capable of measuring the amount of charges of a processing liquid discharged from a nozzle and a processing liquid scattered on a surface of a bowl, calculating a predicted amount of charges of a substrate, and charging a processing liquid supplied in a subsequent process to cancel out the amount of charges of the substrate.

According to an aspect of the present disclosure, a substrate processing apparatus includes a substrate support portion supporting a substrate, a first discharge unit including a first nozzle discharging a first processing liquid to the substrate, a first measurement unit connected to the first nozzle and measuring a first amount of charges of the first processing liquid discharged from the first nozzle, a bowl disposed around the substrate support portion, a second measurement unit measuring a second amount of charges of the first processing liquid scattered from the substrate to the surface of the bowl, and a second discharge unit including a second nozzle discharging a second processing liquid charged based on a difference between the first amount of charges and the second amount of charges to the substrate.

According to another aspect of the present disclosure, a substrate processing method includes disposing a substrate, discharging a first processing liquid from a first nozzle to the substrate, measuring a first amount of charges of the first processing liquid discharged from the first nozzle, measuring a second amount of charges of the first processing liquid scattered from the substrate to a surface of a bowl disposed around the substrate, and discharging a second processing liquid charged based on a difference between the first amount of charges and the second amount of charges from a second nozzle to the substrate.

According to another aspect of the present disclosure, a substrate processing apparatus includes a substrate support portion supporting a substrate, a first nozzle discharging a first processing liquid to the substrate, a first measurement unit including a first nozzle electrode formed in at least a portion of the first nozzle and a first current measurement circuit connected to the first nozzle electrode and measuring a first amount of charges of the first processing liquid discharged from the first nozzle, a bowl disposed around the substrate support portion and connected to a recovery line recovering the first processing liquid scattered from the substrate, a second measurement unit including a bowl electrode formed in at least a portion of the bowl and a second current measurement circuit connected to the bowl electrode and measuring a second amount of charges of the first processing liquid scattered from the substrate to a surface of the bowl, a second nozzle discharging a second processing liquid to the substrate, and a charging unit including a second nozzle electrode formed in at least a portion of the second nozzle and a charging circuit connected to the second nozzle electrode and charging the second processing liquid based on a difference between the first amount of charges and the second amount of charges.

### BRIEF DESCRIPTION OF DRAWINGS

The above and other aspects, features, and advantages of the present disclosure will be more clearly understood from the following detailed description, taken in conjunction with the accompanying drawings, in which: FIG. 1 illustrates a substrate processing apparatus according to an embodiment of the present disclosure;

FIG. 2 illustrates a cross-section of a first discharge unit of a substrate processing apparatus according to an embodiment of the present disclosure;

FIG. 3 illustrates a cross-section of a portion including a bowl in a substrate processing apparatus according to an embodiment of the present disclosure;

FIG. 4A illustrates the arrangement of a bowl electrode in a substrate processing apparatus according to an embodiment of the present disclosure;

FIG. 4B illustrates the arrangement of a bowl electrode in a substrate processing apparatus according to another embodiment of the present disclosure;

FIG. 5 illustrates a cross-section of a second discharge unit of a substrate processing apparatus according to an embodiment of the present disclosure;

FIG. 6 is a flowchart of a substrate processing method according to an embodiment of the present disclosure;

FIG. 7 is a flowchart of a substrate processing method according to an embodiment of the present disclosure; and

FIG. 8 illustrates a cross-section of a portion of a substrate processing apparatus according to another embodiment of the present disclosure.

### DETAILED DESCRIPTION

Hereinafter, exemplary embodiments will be described in detail with reference to the accompanying drawings such that they may be easily practiced by those skilled in the art to which the present disclosure pertains. In describing the present disclosure, if a detailed explanation for a related known function or construction is considered to unnecessarily divert the gist of the present disclosure, such explanation will be omitted but would be understood by those skilled in the art. Also, similar reference numerals are used for the similar parts throughout the specification. In this disclosure, terms, such as “above,” “upper portion,” “upper surface,” “below,” “lower portion,” “lower surface,” “lateral surface,” and the like, are determined based on the drawings, and in actuality, the terms may be changed according to a direction in which a device or an element is disposed.

It will be understood that when an element is referred to as being “connected to” another element, it may be directly connected to the other element or intervening elements may also be present. In contrast, when an element is referred to as being “directly connected to” another element, no intervening elements are present. In addition, unless explicitly described to the contrary, the word “comprise” and variations, such as “comprises” or “comprising,” will be understood to imply the inclusion of stated elements but not the exclusion of any other elements.

FIG. 1 illustrates a substrate processing apparatus according to an embodiment of the present disclosure. A substrate processing apparatus 100 processes a substrate W by discharging a processing liquid onto a surface of the substrate W. The substrate processing apparatus 100 may be provided, for example, in a chamber.

The processing liquid is a liquid substance including one or more components and may be used to process the surface of the substrate W. The processing liquid may be, for example, any one of an anti-reflection coating solution forming an anti-reflection coating (ARC) on the surface of the substrate W, a pre-wet liquid, a cleaning liquid, pure water, or a chemical liquid including one or more organic solvent components.

Referring to FIG. 1, the substrate processing apparatus 100 may include a substrate support portion 110, a discharge unit 120, and a bowl 130.

The substrate support portion 110 may support the substrate W. The substrate W may be disposed on the substrate support portion 110 so that a lower surface thereof is supported by the substrate support portion 110 and an upper surface thereof is exposed.

The substrate support portion 110 may include a mounting table 111 including a mounting surface on which the substrate W is disposed, a rotating shaft 112 supporting the mounting table 111 in a lower portion of the mounting table 111, and a rotating shaft driving unit 113.

The rotating shaft 112 may rotate using the energy generated by the rotating shaft driving unit 113. As the rotating shaft 112 rotates in one direction, the mounting table 111 connected to the rotating shaft may rotate in the same direction as that of the rotating shaft 112.

The substrate processing apparatus 100 may include the discharge unit 120 supplying one or more processing liquids to the substrate W disposed on the substrate support portion 110.

The discharge unit 120 may include a nozzle support portion 121 and one or more nozzles. The nozzle support portion 121 may support one or more nozzles and may adjust a horizontal or vertical position and angle of the one or more nozzles.

The discharge unit 120 may supply different processing liquids to the substrate W. For example, the substrate processing apparatus 100 may include a first discharge unit supplying a first processing liquid to the substrate W and a second discharge unit supplying a second processing liquid, different from the first processing liquid.

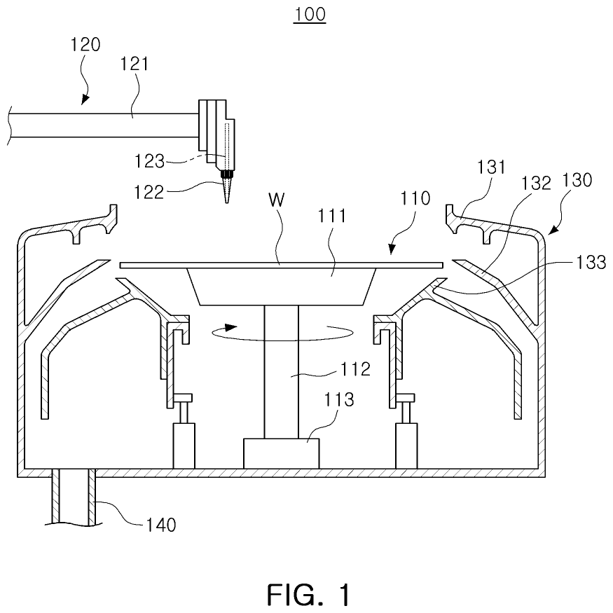

FIG. 2 illustrates a cross-section of the first discharge unit of the substrate processing apparatus 100 according to an embodiment of the present disclosure.

Referring to FIGS. 1 and 2 together, the first discharge unit may include a first nozzle 122.

The first discharge unit may discharge the first processing liquid to the substrate W using the first nozzle 122. The first processing liquid may include, for example, an anti-reflective coating solution.

The nozzle support portion 121 may support the first nozzle 122. The nozzle support portion 121 may adjust a position and angle of the first nozzle 122.

A first supply flow path 21 may be formed inside the nozzle support portion 121 to supply the first processing liquid to the first nozzle 122. A first discharge flow path 22 connected to the first supply flow path 21 and through which the first processing liquid supplied from the first supply flow path 21 is discharged toward the substrate W may be formed inside the first nozzle 122.

The first processing liquid supplied from a source of the first processing liquid may be discharged to the substrate W through the first supply flow path 21 formed inside the nozzle support portion 121 and the first discharge flow path 22 formed inside the first nozzle 122.

The substrate processing apparatus 100 may include a first measurement unit including a first nozzle electrode 123 and a first current measurement circuit 201. The first nozzle electrode 123 may be disposed on a surface of the first discharge flow path 22 or inside the first nozzle 122.

In an embodiment, the first nozzle electrode 123 may have a circular pillar shape surrounding the first discharge flow path 22.

In another embodiment, the first nozzle electrode 123 may have a shape surrounding at least a portion of the first discharge flow path 22.

The first nozzle electrode 123 may be connected to the first current measurement circuit 201 measuring current.

The first measurement unit measures the amount of charges of the first processing liquid discharged from the first nozzle 122 using the first nozzle electrode 123 and the first current measurement circuit 201 connected to the first nozzle electrode 123.

For example, the first measurement unit may derive the amount of charges of the first processing liquid discharged from the first nozzle 122 based on a time integral value of the current flowing through the first nozzle electrode 123.

The first nozzle electrode 123 may be coated with a first shielding film 123a. As the first nozzle electrode 123 is coated with a first shielding film 123a, an error in measurement values occurring due to an external electric field when the amount of charges of the first processing liquid discharged from the first nozzle 122 to the substrate W may is measured may be reduced.

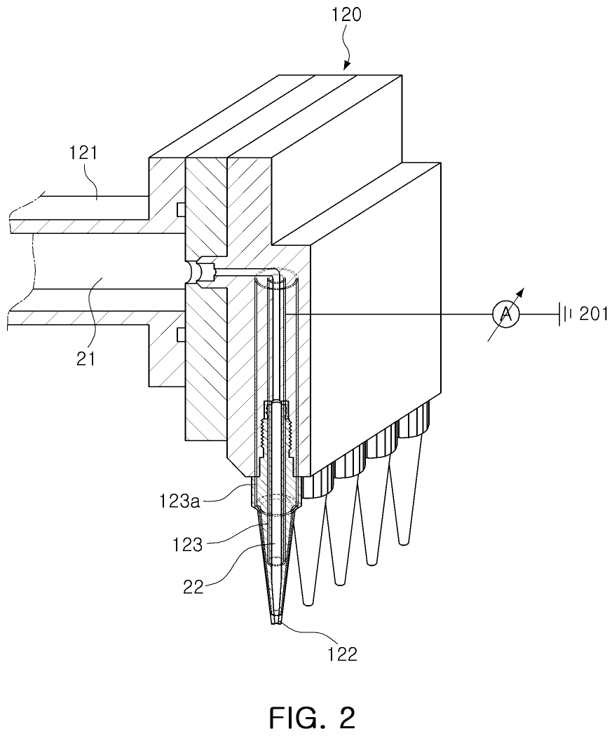

FIG. 3 illustrates a cross-section of a portion including the bowl 130 in the substrate processing apparatus 100 according to an embodiment of the present disclosure.

Referring to FIGS. 1 and 3 together, the bowl 130 may be disposed around the substrate support portion 110. The bowl 130 may be installed to surround the substrate support portion 110, and a processing space in which one or more processing processes for the substrate W is performed may be provided inside the bowl 130.

While the processing liquid is supplied to the substrate W by the substrate processing apparatus 100 and the processing process for the substrate W is performed, a portion of the supplied processing liquid may be scattered to a surface of the bowl 130 from the substrate W.

In an embodiment, the bowl 130 may include an upper bowl 131, a middle bowl 132, and a lower bowl 133.

The upper bowl 131 may be located above a mounting surface of the mounting table 111 on which the substrate W is disposed, the lower bowl 133 may be located below the mounting surface of the mounting table 111, and the middle bowl 132 may be located at a height between the upper bowl 131 and the lower bowl 133.

The substrate processing apparatus 100 may further include a second measurement unit including a bowl electrode and a second current measurement circuit 300.

The bowl electrode may be disposed on a surface of the bowl 130 or inside the bowl 130. The bowl electrode may include a first bowl electrode 134, a second bowl electrode 135, and a third bowl electrode 136.

The first bowl electrode 134 may be disposed on a portion of the surface of the upper bowl 131 or inside the upper bowl 131. The second bowl electrode 135 may be disposed on a portion of the surface of the middle bowl 132 or inside the middle bowl 132. The third bowl electrode 136 may be disposed on a portion of the surface of the lower bowl 133 or inside the lower bowl 133.

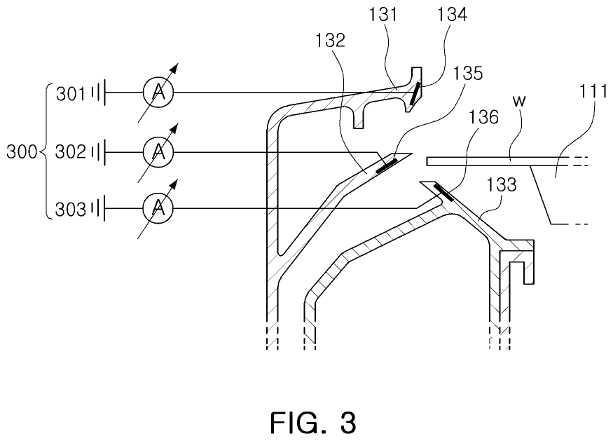

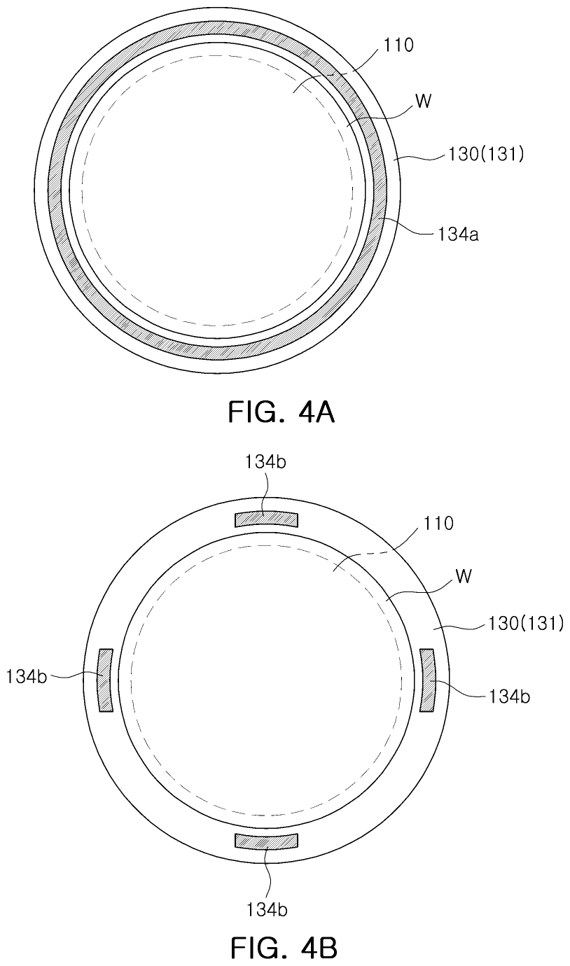

FIGS. 4A and 4B illustrate the arrangement of bowl electrodes 134, 135, and 136 in the substrate processing apparatus 100 according to an embodiment of the present disclosure.

In an embodiment, the first bowl electrode 134a included in the upper bowl 131 may have a circular ring shape disposed along the perimeter of the substrate support portion 110 as shown in FIG. 4A when the substrate processing apparatus 100 is viewed from above.

In another embodiment, a first bowl electrode 134b included in the upper bowl 131 may have a circular arc shape disposed along a portion of the circumference of the substrate support portion 110 as shown in FIG. 4B when the substrate processing apparatus 100 is viewed from above. For example, the first bowl electrode 134b may be disposed around the substrate support portion 110 at intervals of 90 degrees.

The arrangement of the bowl electrodes shown in FIGS. 4A and 4B may be similarly applied to the second bowl electrode 135 included in the middle bowl 132 or the third bowl electrode 136 included in the lower bowl 133.

The bowl electrode may be disposed at one or more points around the substrate support portion 110 to which the processing liquid is mainly scattered when the processing process is performed on the substrate W.

Alternatively, the bowl electrodes may be disposed at one or more points around the substrate support portion 110 excluding a portion in which a large amount of deposits occur during the processing process.

In addition to the circular ring shape or circular arc shape, the bowl electrode may have other shapes, such as circle, square, semicircle, or oval.

The substrate processing apparatus 100 may further include the second current measurement circuit 300 measuring current of the bowl electrode. The second current measurement circuit 300 may include a first bowl current measurement circuit 301, a second bowl current measurement circuit 302, and a third bowl current measurement circuit 303.

As shown in FIG. 3, the first bowl electrode 134 may be connected to a first bowl current measurement circuit 301 for measuring current, the second bowl electrode 135 may be connected to a second bowl current measurement circuit 302 for measuring current, and the third bowl electrode 136 may be connected to a third bowl current measurement circuit 303 measuring current.

The second measurement unit may measure the amount of charges of the first processing liquid scattered from the substrate W to the surface of the bowl 130 using the bowl electrode and the second current measurement circuit 300 connected to the bowl electrode.

For example, the second measurement unit may derive the amount of charges of the first processing liquid scattered onto the surface of the bowl 130 based on a time integral value of the current flowing through the bowl electrodes 134, 135, and 136.

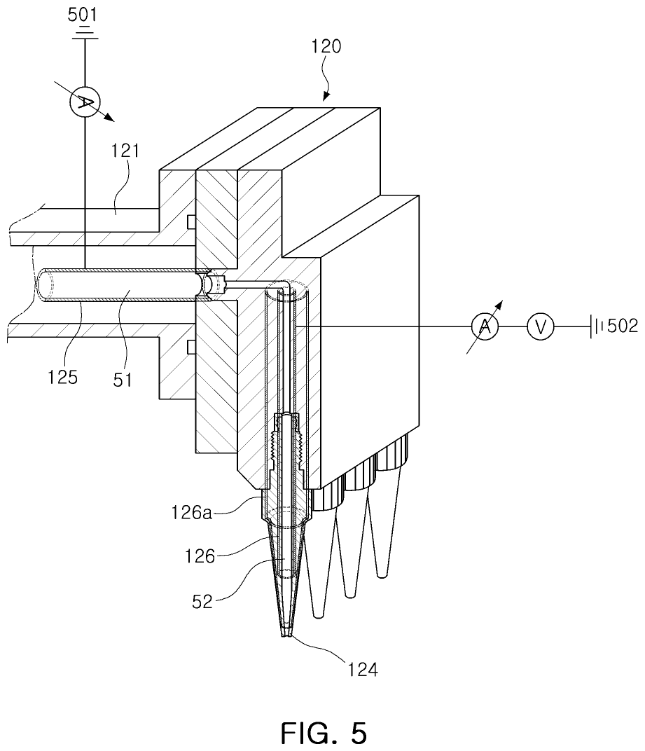

FIG. 5 illustrates a cross-section of a second discharge unit of the substrate processing apparatus according to an embodiment of the present disclosure.

Referring to FIGS. 1 and 5 together, the second discharge unit may include a second nozzle 124.

The second discharge unit may discharge the second processing liquid to the substrate W using the second nozzle 124. The second processing liquid may include, for example, a prewet liquid.

The nozzle support portion 121 may support the second nozzle 124. The nozzle support portion 121 may adjust a position and angle of the second nozzle 124.

A second supply flow path 51 may be formed inside the nozzle support portion 121 to supply the second processing liquid to the second nozzle 124. Inside the second nozzle 124, a second discharge flow path 52 may be formed to be connected to the second supply flow path 51 and discharge the second processing liquid supplied from the second supply flow path 51 toward the substrate W.

The second processing liquid supplied from a source of the second processing liquid may be discharged to the substrate W through the second supply flow path 51 formed inside the nozzle support portion 121 and the second discharge flow path 52 formed inside the second nozzle 124.

The substrate processing apparatus 100 may further include a third measurement unit and a charging unit.

The third measurement unit may include a supply path electrode 125 and a third current measurement circuit 501. The supply flow path electrode 125 may be disposed on the surface of the second supply flow path 51 or inside the nozzle support portion 121.

In an embodiment, the supply flow path electrode 125 may have a circular ring pillar shape surrounding the second supply flow path 51.

In another embodiment, the supply flow path electrode 125 may have a shape surrounding at least a portion of the second supply flow path 51.

The supply flow path electrode 125 may be connected to the third current measurement circuit 501 measuring current.

The third measurement unit may measure the amount of charges of the second processing liquid supplied to the second nozzle 124 through the second supply flow path 51 using the supply flow path electrode 125 and the third current measurement circuit 501 connected to the supply flow path electrode 125.

For example, the third measurement unit may derive the amount of charges of the second processing liquid supplied to the second nozzle 124 through the second supply flow path 51 based on a time integral value of the current flowing through the supply flow path electrode 125.

The charging unit may include a second nozzle electrode 126 and a charging circuit 502. The second nozzle electrode 126 may be disposed on the surface of the second discharge flow path 52 or inside the second nozzle 124.

In an embodiment, the second nozzle electrode 126 may have a circular ring pillar shape surrounding the second discharge flow path 52.

In another embodiment, the second nozzle electrode 126 may have a shape surrounding at least a portion of the second discharge flow path 52.

The second nozzle electrode 126 may be coated with a second shielding film 126a. Since the second nozzle electrode 126 is coated with the second shielding film 126a, the influence of an external electric field may be reduced when the second processing liquid discharged from the second nozzle 124 to the substrate W is charged.

The second nozzle electrode 126 may be connected to the charging circuit 502.

The charging unit may charge the second processing liquid discharged from the second nozzle 124 using the second nozzle electrode 126 and the charging circuit 502 connected to the second nozzle electrode 126.

For example, the charging unit may charge the second processing liquid discharged from the second nozzle 124 so that the second processing liquid has the amount of charges canceling out the amount of charges of the substrate W.

The substrate processing apparatus 100 may further include a controller controlling each component of the substrate processing apparatus 100. The controller may control the charging circuit 502, for example.

The controller may calculate a predicted amount of charges of the substrate W after the processing process using the first processing liquid is performed. The predicted amount of charges of the substrate W may be calculated based on a difference between the amount of charges of the first processing liquid discharged from the first nozzle 122 and the amount of charges of the first processing liquid scattered from the substrate W to the surface of the bowl 130.

The controller may control the charging circuit 502 so that the second processing liquid has the amount of charges canceling out the predicted amount of charges of the substrate W. For example, the controller may control the charging circuit 502 to apply a voltage to the second nozzle electrode 126 so that the second processing liquid has the amount of charges canceling out the sum of the predicted amount of charges of the substrate W after the processing process using the first processing liquid is performed and the amount of charges of the second processing liquid supplied through the second supply flow path 51 of the second discharge unit.

In another embodiment, the substrate processing apparatus may include a plurality of nozzles connected to different nozzle support portions and discharging different processing liquids.

Referring back to FIG. 1, the substrate processing apparatus 100 may further include a recovery unit 140 recovering the processing liquid used to process the substrate W. The recovery unit 140 may be connected to a lower portion of the bowl 130 installed to surround the substrate support portion 110.

The recovery unit 140 may include one or more recovery lines. For example, the recovery unit 140 may include a recovery line extending downwardly from the bottom of the bowl 130.

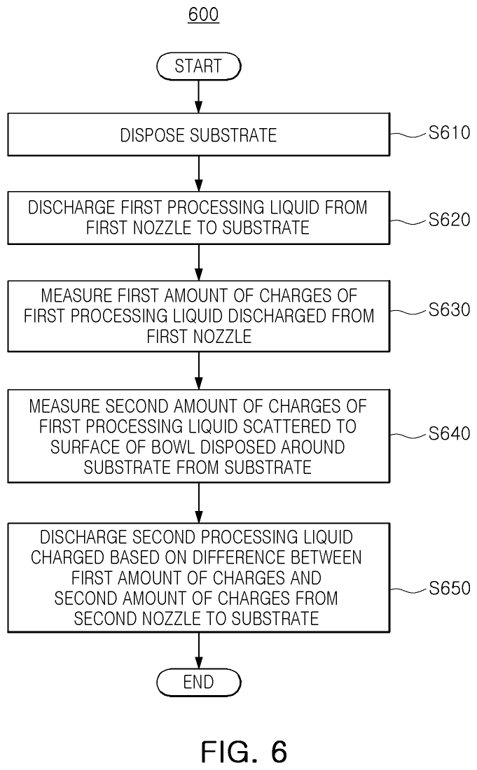

FIG. 6 is a flowchart of a substrate processing method according to an embodiment of the present disclosure.

As shown in FIG. 6, the substrate processing method includes an operation (S610) of disposing a substrate, an operation (S620) of discharging a first processing liquid from a first nozzle to the substrate, an operation (S630) of measuring a first amount of charges of the first processing liquid discharged from the first nozzle, an operation (S640) of measuring a second amount of charges of the first processing liquid scattered to a surface of a bowl disposed around the substrate from the substrate, and an operation (S650) of discharging a second processing liquid charged based on a difference between the first amount of charges and the second amount of charges to the substrate from a second nozzle.

In the operation (S620) of discharging the first processing liquid, the first processing liquid may include an anti-reflection coating solution. By supplying the first processing liquid to the surface of the substrate, an anti-reflection film forming processing process may be performed on the surface of the substrate.

In the operation (S630) of measuring the first amount of charges, the current flowing through the first nozzle electrode disposed on the surface of the flow path of the first nozzle or inside the first nozzle may be measured. The first amount of charges may be derived, for example, based on a time integral value of the current flowing through the first nozzle electrode.

In the operation (S640) of measuring the second amount of charges, the current flowing through a bowl electrode disposed on a surface of the bowl or inside the bowl may be measured. The second amount of charges may be derived, for example, based on a time integral value of the current flowing through the bowl electrode.

In the operation (S650) of discharging the second processing liquid (S650), the second processing liquid may include a prewet liquid. A prewet processing process may be performed on the surface of the substrate by supplying the second processing liquid to the surface of the substrate.

Since the second processing liquid discharged to the substrate in the operation (S650) of discharging the second processing liquid has the amount of charges canceling out the predicted amount of charges of the substrate, adverse effects occurring in a subsequent substrate processing process due to a charging phenomenon of the substrate may be reduced.

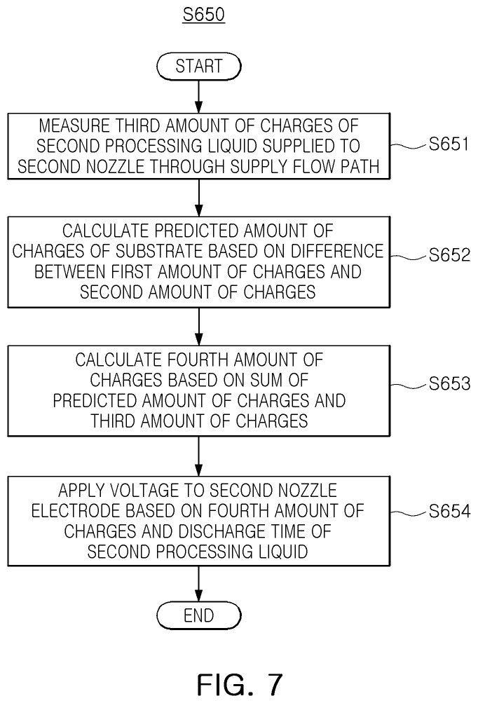

FIG. 7 is a detailed flowchart of the operation (S650) of discharging the second processing liquid. As shown in FIG. 7, the operation (S650) of discharging the second processing liquid may include an operation (S651) of measuring a third amount of charges of the second processing liquid supplied to the second nozzle through the supply flow path, an operation (S652) of calculating a predicted amount of charges of the substrate based on the difference between the first amount of charges and the second amount of charges, an operation (S653) of calculating a fourth amount of charges based on the sum of the predicted amount of charges and the third amount of charges, and an operation (S654) of applying voltage to the second nozzle electrode based on the fourth amount of charges and a discharge time of the second processing liquid.

In the operation (S651) of measuring the third amount of charges, current flowing through the supply flow path electrode disposed on the surface of the supply flow path through which the second processing liquid is supplied or inside the supply flow path may be measured. The third amount of charges may be derived, for example, based on a time integral value of the current flowing through the supply flow path electrode.

In the operation (S652) of calculating the predicted amount of charges of the substrate, the first amount of charges may be derived based on the time integral value for the current flowing through the first nozzle electrode, and the second amount of charges may be derived based on the time integral value for the current flowing through the bowl electrode. For example, when the first amount of charges has a value of Q1 and the second amount of charges has a value of Q2, the predicted amount of charges of the substrate may be calculated as (Q1−Q2).

In the operation (S653) of calculating the fourth amount of charges, for example, when the predicted amount of charges of the substrate has the value of (Q1−Q2) and the third amount of charges has the value of Q3, Q4, the value of the fourth amount of charges, may be calculated to have a value satisfying (Q1−Q2)+ (Q3+Q4)=0. That is, the fourth amount of charges may be calculated as (−Q1+Q2−Q3).

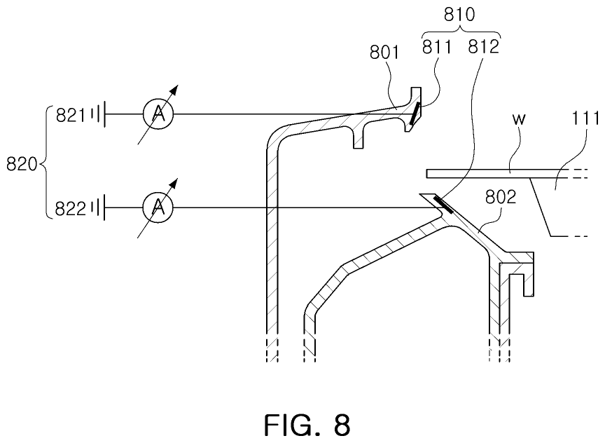

FIG. 8 illustrates a portion of a substrate processing apparatus according to another embodiment of the present disclosure. As shown in FIG. 8, the substrate processing apparatus may include an upper bowl 801 and a lower bowl 802.

The upper bowl 801 may be located above the mounting surface of the mounting table 111 on which the substrate W is disposed, and the lower bowl 802 may be located below the mounting surface of the mounting table 111.

The substrate processing apparatus may further include a bowl electrode and a bowl current measurement circuit 820.

The bowl electrode may include an upper bowl electrode 811 disposed in a portion of the surface of the upper bowl 801 or inside the upper bowl 801 and a lower bowl electrode 812 disposed in a portion of the surface of the lower bowl 802 or inside the lower bowl 802.

The bowl current measurement circuit 820 may include an upper current measurement circuit 821 and a lower current measurement circuit 822. The upper bowl electrode 811 may be connected to the upper current measurement circuit 821 measuring current. The lower bowl electrode 812 may be connected to the lower current measurement circuit 822 measuring current.

In the embodiment shown in FIG. 8, the substrate processing apparatus may measure the amount of charges of a processing liquid scattered from the substrate W to the surface of the upper bowl 801 and the surface of the lower bowl 802 using the upper bowl electrode 811, the lower bowl electrode 812, and the bowl current measurement circuit 820.

Even when the number and shape of the bowls are different from the examples shown in FIGS. 1, 3 and 8,
if the bowl is provided so that the processing liquid is scattered onto the surface of the bowl, the substrate processing method described above may be similarly applied by measuring the amount of charges of the processing liquid scattered onto the surface of the bowl.

The present disclosure may provide the substrate processing apparatus and the substrate processing method capable of compensating for the amount of charges of the substrate, while performing a prewet processing process through the above configuration.

The embodiment of the present disclosure may provide the substrate processing apparatus and the substrate processing method capable of measuring the amount of charges of the processing liquid discharged from the nozzle and the processing liquid scattered onto the surface of the bowl, calculating a predicted amount of charges of the substrate, and charging the processing liquid supplied in a subsequent process, thereby canceling out the amount of charges of the substrate.

In addition, in describing the present disclosure, “˜ part’ or ‘unit’ may be implemented by various methods, for example, a processor, program instructions executed by the processor, a software module, microcode, a computer program product, a logic circuit, an application-specific integrated circuit, firmware, etc.

The contents of the method disclosed in the embodiments of the present application may be implemented directly with a hardware processor or may be implemented and completed through a combination of hardware and software modules among processors. The software module may be stored in conventional storage medium, such as random access memory, flash memory, read-only memory, programmable read-only memory, or electrically erasable programmable memory, a register, etc. The storage medium is located in a memory, and the processor reads information stored in the memory and combines it with the hardware to complete the contents of the method described above. To prevent duplication, detailed description is omitted here.

In the implementation process, each contents of the aforementioned method may be completed by instructions in the form of software or a logically integrated circuit of hardware among processors. The contents of the method disclosed in the embodiments of the present application may be implemented directly by a hardware processor or may be implemented and completed through a combination of hardware and software modules among the processors. The software module may be stored in conventional storage mediums, such as random access memory, flash memory, read-only memory, programmable read-only memory, or electrically erasable programmable memory, a register, etc. The storage medium is located in a memory, and the processor reads information stored in the memory and combines it with the hardware to complete the contents of the method described above.

That is, those skilled in the art will know that each exemplary unit and algorithm operation described in the embodiments disclosed herein may be combined and realized by electronic hardware or a combination of computer software and electronic hardware. Whether these functions are performed by hardware or software is determined by a specific application and design constraints of a technical method. Those skilled in the art may implement the described functionality using different methods for each particular application, but such implementation should not be considered beyond the scope of the present application.

In some embodiments provided in the present application, it should be understood that the disclosed devices and methods may be implemented in other manners. For example, the device embodiments described above are merely illustrative. For example, the division of the units is only a kind of logical function division, and there may be other division methods in actual implementation. For example, a plurality of units or assemblies may be combined with or integrated into another system or some features may be ignored or may not be performed. Meanwhile, coupling or direct coupling or communication connection between each other shown or described may be indirect coupling or communication connection through some interfaces, devices or units and may be electrical, mechanical or other form.

Units described above as separate components may be physically separated, and components displayed as units may or may not be physical units, that is, they may be located in one place or distributed across a plurality of network units. Some or all of the units may be selected according to actual demand to realize the purpose of the scheme of the present embodiment.

That is, each functional unit in each embodiment of the present application may be integrated into one processing unit, each unit may exist alone, or two or more units may be integrated into one unit.

If the above function is implemented in the form of a software function unit and sold or used as an independent product, it may be stored in a single computer-readable storage medium. Based on this understanding, the portion of the technical solution of the present application that is essentially contributed to the prior art or a portion of the technical solution may be implemented in the form of a software product, and the computer software product may be stored in a storage medium, so that a computing device (which may be a personal computer, server, or network device, etc.) including some instructions may perform all or portion of the steps of the method described in each embodiment of the present application. The aforementioned storage mediums include various mediums that may store program code, such as a USB memory, a mobile hard disk, read-only memory (ROM), random access memory (RAM), a magnetic disk, or CD-ROM.

The present disclosure is not limited by the aforementioned embodiments and accompanying drawings. The scope of the present disclosure is limited by the appended claims, and it is understood by those skilled in the art that various forms of substitution, modification, and change may be made without departing from the technical spirit of the present disclosure as set forth in the claims.

What is claimed is:

1. A substrate processing apparatus comprising:
a substrate support portion supporting a substrate;
a first discharge unit including a first nozzle discharging a first processing liquid to the substrate;
a first measurement unit connected to the first nozzle and measuring a first amount of charges of the first processing liquid discharged from the first nozzle;
a bowl disposed around the substrate support portion;
a second measurement unit measuring a second amount of charges of the first processing liquid scattered from the substrate to the surface of the bowl; and
a second discharge unit including a second nozzle discharging a second processing liquid charged based on a difference between the first amount of charges and the second amount of charges to the substrate.

2. The substrate processing apparatus of claim 1, wherein
the first measurement unit includes:
a first nozzle electrode disposed on a surface of a flow path of the first nozzle or inside the first nozzle; and
a first current measurement circuit connected to the first nozzle electrode.

3. The substrate processing apparatus of claim 2, wherein the first nozzle electrode is coated with a shielding film shielding an external electric field.

4. The substrate processing apparatus of claim 1, wherein
the second measurement unit includes:
a bowl electrode disposed on a surface of the bowl or inside the bowl; and
a second current measurement circuit connected to the bowl electrode.

5. The substrate processing apparatus of claim 4, wherein
the bowl includes:
an upper bowl located above a mounting surface of the substrate support portion on which the substrate is disposed;
a lower bowl located below the mounting surface; and
a middle bowl located between the upper bowl and the lower bowl, and
the bowl electrode includes:
a first bowl electrode disposed in at least a portion of the upper bowl;
a second bowl electrode disposed in at least a portion of the lower bowl; and
a third bowl electrode disposed in at least a portion of the middle bowl.

6. The substrate processing apparatus of claim 1, wherein
the second discharge unit includes:
a third measurement unit measuring a third amount of charges of the second processing liquid supplied to the second nozzle through a supply flow path; and
a charging unit charging the second processing liquid discharged from the second nozzle.

7. The substrate processing apparatus of claim 6, wherein
the third measurement unit includes:
a supply flow path electrode disposed on a surface of the supply flow path or inside the supply flow path; and
a third current measurement circuit connected to the supply flow path electrode.

8. The substrate processing apparatus of claim 1, wherein
the charging unit includes:
a second nozzle electrode disposed on a surface of a flow path of the second nozzle or inside the second nozzle; and
a charging circuit connected to the second nozzle electrode.

9. The substrate processing apparatus of claim 8, further comprising:
controller controlling the charging circuit,
wherein the controller calculates a predicted amount of charges of the substrate based on the difference between the first amount of charges and the second amount of charges and controls the charging circuit so that the second processing liquid discharged from the second nozzle to the substrate has a fourth amount of charges canceling out the predicted amount of charges.

10. The substrate processing apparatus of claim 1, wherein
the first processing liquid is an anti-reflective coating solution, and
the second processing liquid is a prewet liquid.

11. A substrate processing method comprising:
disposing a substrate;
discharging a first processing liquid from a first nozzle to the substrate;
measuring a first amount of charges of the first processing liquid discharged from the first nozzle;
measuring a second amount of charges of the first processing liquid scattered from the substrate to a surface of a bowl disposed around the substrate; and
discharging a second processing liquid charged based on a difference between the first amount of charges and the second amount of charges from a second nozzle to the substrate.

12. The substrate processing method of claim 11, wherein the measuring of the first amount of charges includes measuring current flowing through a first nozzle electrode disposed on a surface of a flow path of the first nozzle or inside the first nozzle.

13. The substrate processing method of claim 10, wherein the measuring of the second amount of charges includes measuring current flowing through a bowl electrode disposed on the surface of the bowl or inside the bowl.

14. The substrate processing method of claim 11, wherein
the discharging of the second processing liquid includes:
measuring a third amount of charges of the second processing liquid supplied to the second nozzle through a supply flow path; and
charging the second processing liquid discharged from the second nozzle so that the second processing liquid has a fourth amount of charges.

15. The substrate processing method of claim 14, wherein the measuring of the third amount of charges includes measuring current flowing through a supply flow path electrode disposed on a surface of the supply flow path or inside the supply flow path.

16. The substrate processing method of claim 14, wherein
the charging of the second processing liquid includes:
calculating a predicted amount of charges of the substrate based on a difference between the first amount of charges and the second amount of charges; and
calculating the fourth amount of charges based on a sum of the predicted amount of charges and the third amount of charges.

17. The substrate processing method of claim 16, wherein the charging of the second processing liquid further includes applying voltage to a second nozzle electrode disposed on a surface of a flow path of the second nozzle or inside the second nozzle based on the fourth amount of charges and a discharge time of the second processing liquid.

18. The substrate processing method of claim 11, wherein
the first processing liquid is an anti-reflective coating solution, and
the second processing liquid is a prewet liquid.

19. A substrate processing apparatus comprising:
a substrate support portion supporting a substrate;
a first nozzle discharging a first processing liquid to the substrate;
a first measurement unit including a first nozzle electrode formed in at least a portion of the first nozzle and a first current measurement circuit connected to the first nozzle electrode and measuring a first amount of charges of the first processing liquid discharged from the first nozzle;
a bowl disposed around the substrate support portion and connected to a recovery line recovering the first processing liquid scattered from the substrate;
a second measurement unit including a bowl electrode formed in at least a portion of the bowl and a second current measurement circuit connected to the bowl electrode and measuring a second amount of charges of the first processing liquid scattered from the substrate to a surface of the bowl;
a second nozzle discharging a second processing liquid to the substrate; and
a charging unit including a second nozzle electrode formed in at least a portion of the second nozzle and a charging circuit connected to the second nozzle electrode and charging the second processing liquid based on a difference between the first amount of charges and the second amount of charges.

20. The substrate processing apparatus of claim 19, wherein the first nozzle electrode and the second nozzle electrode are coated with a shielding film shielding an external electric field.
